(19) United States
(12) Patent Application Publication
(10) Pub. No.: US 2026/0213500 A1
(43) Pub. Date: Jul. 23, 2026

(54) ION WIND GENERATING DEVICE AND HEAT DISSIPATION SYSTEM

(71) Applicant: Suzhou Anminrui Electronic Technology Co., Ltd., Kunshan City (CN)

(72) Inventors: Hai Xu, Kunshan City (CN); Ni-Ming Xu, Kunshan City (CN); Shou-Zhi Ni, Kunshan City (CN); Hao-Sheng Jiang, Kunshan City (CN)

(73) Assignee: Suzhou Anminrui Electronic Technology Co., Ltd., Kunshan City (CN)

(21) Appl. No.: 19/216,494

(22) Filed: May 22, 2025

(30) Foreign Application Priority Data
Jan. 21, 2025 (TW) 114102545
Jan. 21, 2025 (TW) 114102546

(51) Int. Cl. H01T 23/00; H05K 7/20

(52) U.S. Cl. CPC H01T 23/00; H05K 7/20136

(57) ABSTRACT

A heat dissipation system is provided, including at least one ion wind generating device and ozone removal device. The ion wind generating device and the ozone removal device have the same structure including an insulating frame, an emitter electrode, and a collector electrode. Inner surfaces of the insulating frame form inwardly inclined surfaces and protrusions. The emitter electrode disposed at the middle portion of the insulating frame includes a conductive brush including densely arranged conductive fibers. The collector electrode includes at least one conductive rod. The ion wind generating device and the ozone removal device are respectively disposed on two opposite sides of an electronic component. The ion wind generating device operates under a high potential difference to generate ion wind and ozone, which are blown toward the electronic component to assist in dissipating heat. The ozone removal device operates under a low potential difference to decompose ozone.

### BACKGROUND OF THE INVENTION

### 1. Field of the Invention

The present invention relates to a heat dissipation device and a heat dissipation system using the same, and more particularly to an ion wind generating device capable of generating ion wind and a heat dissipation system using the same to assist in dissipating heat from electronic components.

### 2. Description of the Prior Art

With the trend of electronic products becoming increasingly lighter, thinner, and smaller, conventional heat dissipation devices such as fans and aluminum fins have become less suitable. Additionally, fans may introduce noise issues. Therefore, there is a need for a heat dissipation device that is better suited for use in miniaturized electronic products.

### SUMMARY OF THE INVENTION

The present invention is adapted to provide an ion wind generating device and a heat dissipation system using the same, which are better suited for use in miniaturized electronic products.

According to an aspect of the present invention, there is provided an ion wind generating device. The ion wind generating device includes an insulating frame, an emitter electrode, and a collector electrode. The insulating frame includes a top wall, a bottom wall, and two opposing side walls. The top wall, the bottom wall, and the two side walls define an accommodation space. The accommodation space has an air inlet and an air outlet. Inner surfaces of the two side walls form inwardly inclined surfaces from the air inlet toward the air outlet. The insulating frame further includes a bracket. The bracket is disposed adjacent to the air inlet and has two opposite ends respectively connected to the two side walls. The emitter electrode includes a connecting portion and a conductive brush connected to the connecting portion. The conductive brush includes densely arranged conductive fibers. The connecting portion is mounted on the bracket. The collector electrode includes at least one conductive rod. Each conductive rod is disposed adjacent to the air outlet and has two opposite ends respectively connected to the two side walls.

According to another aspect of the present invention, there is provided a heat dissipation system for an electronic component. The heat dissipation system includes at least one above-mentioned ion wind generating device and at least one ozone removal device. The ion wind generating device and the ozone removal device has the same structure. Each ion wind generating device is disposed on one side of the electronic component with its air outlet facing the electronic component, and each ozone removal device is disposed on an opposite side of the electronic component with its air inlet facing the electronic component. A potential difference between the emitter electrode and the collector electrode of each ion wind generating device is configured to generate ion wind and ozone, and a potential difference between the emitter electrode and the collector electrode of each ozone removal device is configured to decompose the ozone.

The above and other objectives, features, and advantages of the present invention will become more apparent and understandable from the following detailed description of the preferred embodiments, which are provided with reference to the accompanying drawings.

### BRIEF DESCRIPTION OF THE DRAWINGS

FIG. 1 is a perspective view of a heat dissipation system according to an embodiment of the present invention.

FIGS. 2 and 3 are perspective views of a first embodiment of an ion wind generating/ozone removal device of the heat dissipation system shown in FIG. 1, viewed from different angles.

FIGS. 4 and 5 are an exploded perspective view and an exploded top view of the ion wind generating/ozone removal device shown in FIG. 2, respectively.

FIG. 6 is a cross-sectional side view of the ion wind generating/ozone removal device shown in FIG. 2.

FIG. 7 is a cross-sectional side view of a second embodiment of an ion wind generating/ozone removal device.

FIG. 8 is a perspective view of a third embodiment of an ion wind generating device.

### DESCRIPTION OF THE PREFERRED EMBODIMENTS

In the following embodiments, the same or similar reference numerals are used to denote the same or similar elements. Furthermore, directional terms such as up, down, left, right, front, and back are used with reference to the drawings. Therefore, such directional terms are used for descriptive purposes only and are not intended to limit the present invention.

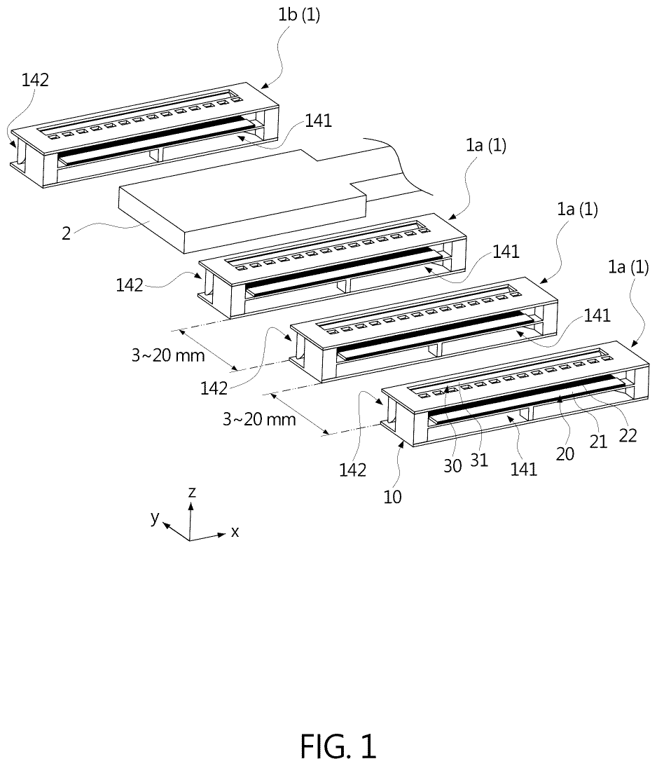

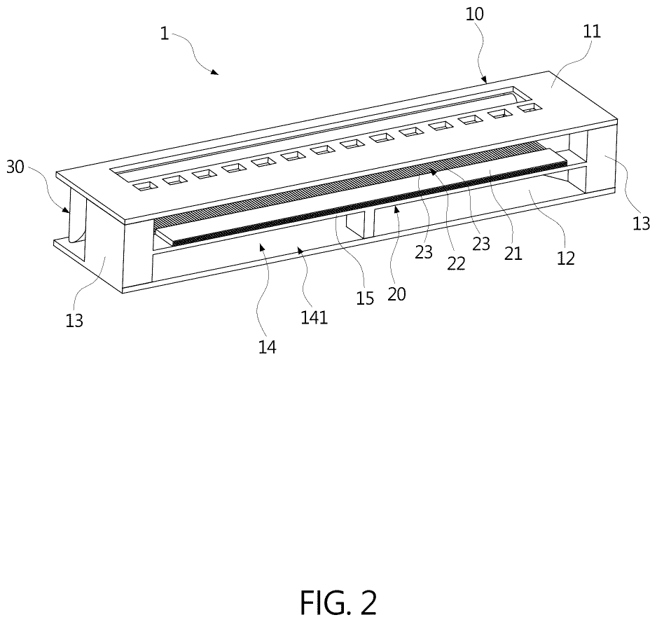

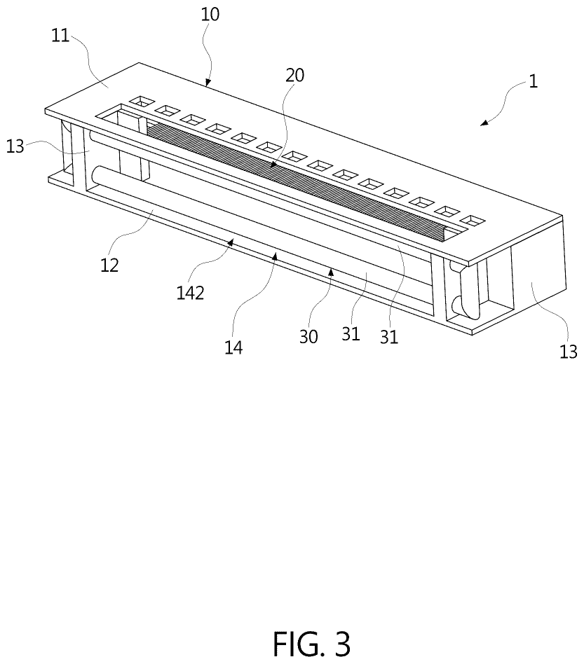

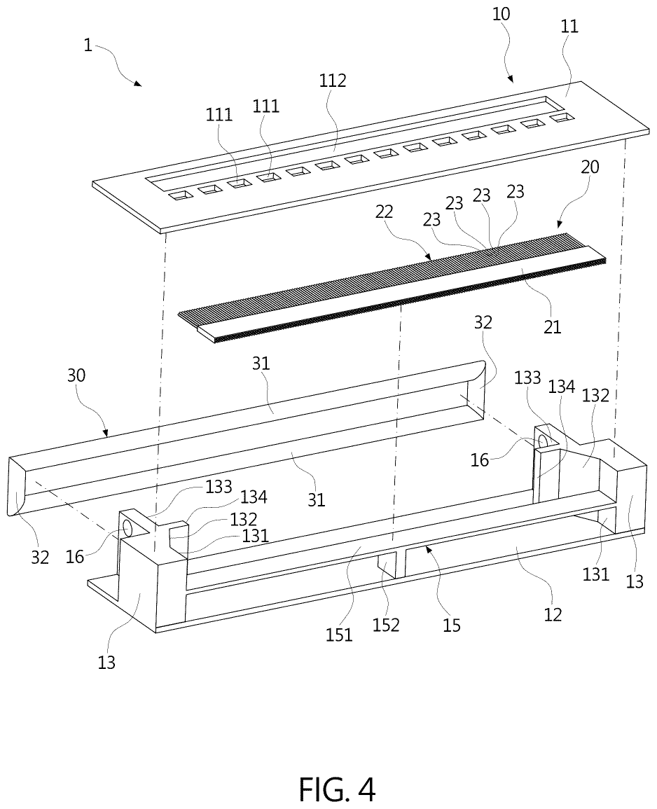

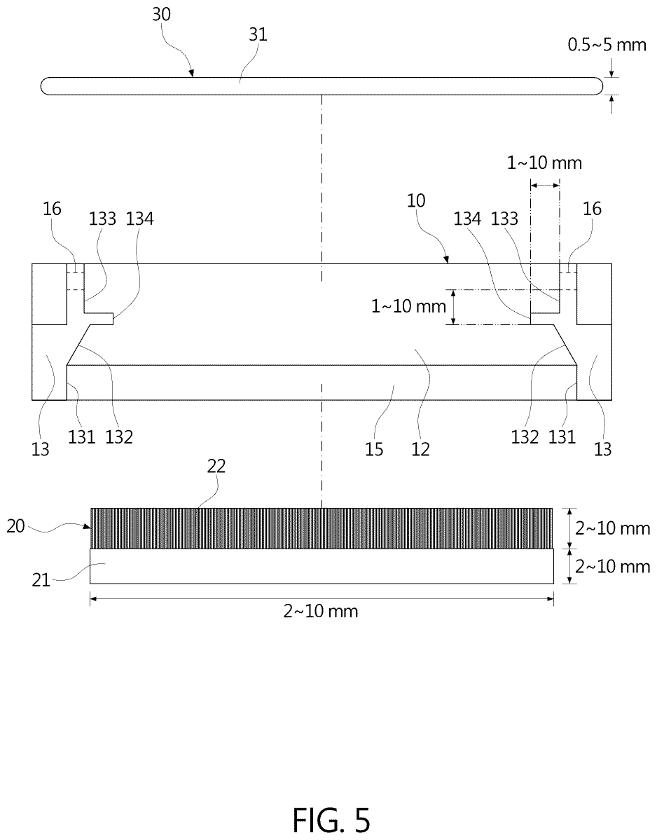

Referring to FIGS. 1 to 5, FIG. 1 is a perspective view of a heat dissipation system according to an embodiment of the present invention; FIGS. 2 and 3 are perspective views of a first embodiment of an ion wind generating/ozone removal device of the heat dissipation system shown in FIG. 1, viewed from different angles; FIGS. 4 and 5 are an exploded perspective view and an exploded top view of the ion wind generating/ozone removal device shown in FIG. 2, respectively. As shown in FIG. 1, the heat dissipation system is used for an electronic component 2. The electronic component 2 may be an electronic element, such as a chip, or a thermal management element, such as a heat pipe or a vapor chamber. The heat dissipation system includes at least one ion wind generating device 1a and at least one ozone removal device 1b. In the embodiment, the heat dissipation system includes three ion wind generating devices 1a and one ozone removal device 1b. The ion wind generating devices 1a and the ozone removal device 1b have the same structure and therefore may be designated by the same reference numeral 1. The same structure of the ion wind generating devices 1a and the ozone removal device 1b facilitates manufacturing and installation. The following description will first focus on the ion wind generating device or the ozone removal device (hereinafter referred to as the ion wind generating/ozone removal device) 1.

As shown in FIGS. 2 and 3, the ion wind generating/ozone removal device 1 includes an insulating frame 10, an emitter electrode 20, and a collector electrode 30. The insulating frame 10 includes a top wall 11, a bottom wall 12, and two opposing side walls 13. The top wall 11, the bottom wall 12, and the two side walls 13 define an accommodation space 14. The accommodation space 14 has an air inlet 141 and an air outlet 142. The insulating frame 10 further includes a bracket 15. The bracket 15 is disposed adjacent to the air inlet 141 and has two opposite ends respectively connected to the two side walls 13. The emitter electrode 20 includes a connecting portion 21 and a conductive brush 22 connected to the connecting portion 21. The conductive brush 22 includes densely arranged conductive fibers 23. The connecting portion 21 is mounted on the bracket 15. The collector electrode 30 includes two conductive rods 31. Each conductive rod 31 is disposed adjacent to the air outlet 142 and has two opposite ends respectively connected to the two side walls 13. However, the present invention is not limited thereto. For example, the collector electrode 30 may alternatively include only one conductive rod 31, or three or more conductive rods 31.

In the embodiment, as shown in FIG. 4, the top wall 11 is detachably connected to the two side walls 13. However, the present invention is not limited thereto. For example, the top wall 11 may be fixedly connected to the two side walls 13 such that the insulating frame 10 is formed in one piece, as long as the insulating frame 10 does not interfere with the installation of the emitter electrode 20 and the collector electrode 30. The top wall 11 may be provided with auxiliary air inlets 111 and 112. The auxiliary air inlets 111 and 112 are square and elongated-shaped, respectively. However, the present invention is not limited thereto. For example, the auxiliary air inlets 111 and 112 may alternatively be circular or take other shapes, as long as their sizes are restricted from being too large, thereby preventing electrical leakage.

In the embodiment, as shown in FIGS. 4 and 5, the inner surfaces of the two side walls 13 respectively and sequentially form, from the air inlet 141 toward the air outlet 142, a first guiding surface 131, an inwardly inclined surface 132, and a second guiding surface 133. Viewed from the air inlet 141 toward the air outlet 142, the first guiding surfaces 131 of the two side walls 13 cooperate with the top wall 11 and the bottom wall 12 to define a large air inlet passage for receiving a greater volume of incoming air. Subsequently, the inwardly inclined surfaces 132 of the two side walls 13 cooperate with the top wall 11 and the bottom wall 12 to define a gradually narrowing air inlet passage, thereby providing a pressurization effect to the incoming air and enhancing the air ionization effect. Finally, the second guiding surfaces 133 of the two side walls 13 cooperate with the top wall 11 and the bottom wall 12 to define an air outlet passage for outputting ion wind. Additionally, the inner surfaces of the two side walls 13 further respectively form a protrusion 134 between the inclined surface 132 and the second guiding surface 133. The emitter electrode 20 is disposed such that it does not extend beyond the protrusion 134. The protrusions 134 of the two side walls 13 serve to constrain a spacing between the emitter electrode 20 and the collector electrode 30, thereby preventing frequent electrical discharges caused by an excessively small spacing, which may hinder ion wind generation. Moreover, the protrusions 134 serve to further reduce the influence of electric arcs generated at two sides of the conductive brush 22 of the emitter electrode 20.

In the embodiment, as shown in FIG. 4, the bracket 15 includes a horizontal supporting plate 151 and a vertical supporting plate 152. The horizontal supporting plate 151 has two opposite ends respectively connected to intermediate-height portions of the two side walls 13. The vertical supporting plate 152 has two opposite ends respectively connected to a middle portion of the horizontal supporting plate 151 and the bottom wall 12. Accordingly, after the emitter electrode 20 is mounted onto the bracket 15, the emitter electrode 20 is approximately disposed at the middle portion of the insulating frame 10 and is spaced apart from the top wall 11 and the bottom wall 12, thereby substantially preventing electric leakage to the outside of the insulating frame 10. Additionally, the design of the horizontal supporting plate 151 and the single vertical supporting plate 152 may allow for increased airflow clearance adjacent to the air inlet 141 while maintaining the structural stability of the bracket 15. However, the present invention is not limited thereto. For example, the bracket 15 may alternatively include only the horizontal supporting plate 151 without the vertical supporting plate 152, or may include multiple vertical supporting plates 152, each having two opposite ends respectively connected to the horizontal supporting plate 151 and the bottom wall 12.

In the embodiment, as shown in FIG. 4, each side wall 13 is provided with two connecting holes 16 adjacent to the air outlet 142. The two opposite ends of each conductive rod 31 are respectively connected to the corresponding connecting holes 16 of the two side walls 13. However, the present invention is not limited thereto. For example, each side wall 13 may alternatively be provided with two engaging slots adjacent to the air outlet 142. The two opposite ends of each conductive rod 31 are respectively slid into and securely engaged with or positioned at the terminal ends of the corresponding engaging slots.

In the embodiment, as shown in FIG. 4, the connecting portion 21 of the emitter electrode 20 is a strip-shaped connecting portion. The conductive brush 22 includes at least several hundreds of conductive fibers 23, each having a diameter on the micrometer scale, and the conductive fibers 23 are densely arranged and layered along the strip-shaped connecting portion. After the connecting portion 21 is mounted on the bracket 15, the conductive brush 22 is oriented toward the collector electrode 30. The collector electrode 30 includes two conductive rods 31 and at least one auxiliary conductive rod 32 (two auxiliary conductive rods 32 are used in the embodiment). The auxiliary conductive rods 32 are provided for connecting the two conductive rods 31, thereby electrically connecting the two conductive rods 31. However, the present invention is not limited thereto. For example, the collector electrode 30 may alternatively include only two conductive rods 31 without the auxiliary conductive rods 32. During operation, the emitter electrode 20 is electrically connected to the positive or negative terminal of a DC power source, while the collector electrode 30 is electrically connected to ground or a low potential terminal close to 0 volts.

In one embodiment, as shown in FIGS. 2 and 3, the insulating frame 10 is made of a highly electrically insulating material including, but not limited to, polymer, composite material, or ceramic material. For example, the insulating frame 10 may be made of polytetrafluoroethylene (PTFE), polyetheretherketone (PEEK), alumina ceramic, or aluminum nitride ceramic. The connecting portion 21 of the emitter electrode 20, the conductive fibers 23 of the conductive brush 22, and the conductive rods 31 of the collector electrode 30 are made of conductive materials including, but not limited to, metals, alloys, conductive polymers, or carbon-based materials. For example, the connecting portion 21 may be made of copper foil or aluminum foil; the conductive fibers 23 may include, but are not limited to, carbon fibers, conductive polymer fibers (such as polyacetylene fibers, polyaniline fibers, polypyrrole fibers, polythiophene fibers), carbon black-based fibers, or conductive metal compound fibers; the conductive rod 31 may be made of titanium alloy (such as TC4, TA1, TA2, etc.), nickel-plated plastic, nickel-plated copper, nickel-plated copper alloy, nickel-plated aluminum, nickel-plated aluminum alloy, nickel-plated zinc, nickel-plated zinc alloy, stainless steel, or Nak80 steel. It is noted that nickel-plated plastic refers to electroplating nickel onto the surface of plastic, nickel-plated copper refers to electroplating nickel onto the surface of copper, nickel-plated copper alloy refers to electroplating nickel onto the surface of copper alloy, and the same applies to the others.

Referring to FIG. 5, FIG. 5 is an exploded top view of the ion wind generating/ozone removal device 1 shown in FIG. 2, where the top wall 11 of the insulating frame 10 is omitted. The design of the protrusions 134 and the connecting holes 16 of the insulating frame 10 constrain the spacing between the emitter electrode 20 and the collector electrode 30. In one embodiment, the spacing between the emitter electrode 20 and the collector electrode 30 is between 1 and 10 millimeters. The protrusion 134 has a length of 1 and 10 millimeters. Furthermore, the connecting portion 21 of the emitter electrode 20 has a length of 2 to 10 millimeters and a width of 2 to 10 millimeters. The conductive fibers 23 of the conductive brush 22 have a length of 2 to 10 millimeters. The conductive rod 31 of the collector electrode 30 has a diameter of 0.5 to 5 millimeters.

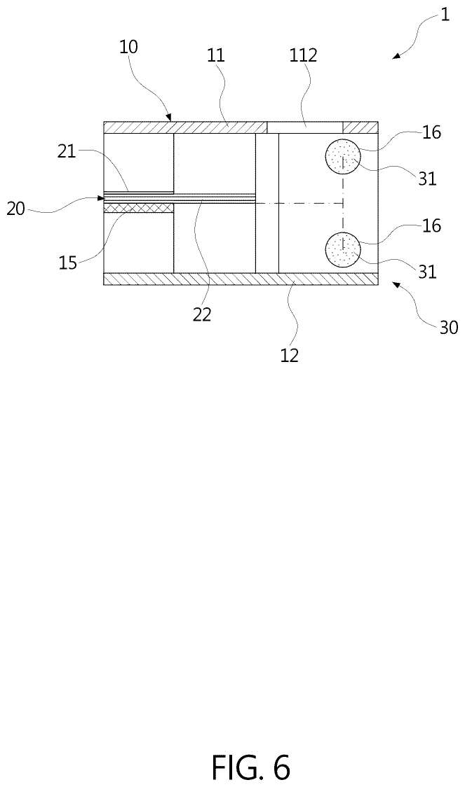

Referring to FIG. 6, FIG. 6 is a cross-sectional side view of the ion wind generating/ozone removal device 1 shown in FIG. 2. In the embodiment, the two conductive rods 31 of the collector electrode 30 are arranged in parallel and vertically spaced from each other. The conductive brush 22 of the emitter electrode 20 is oriented toward the midpoint of the line connecting the centers of the two conductive rods 31. However, the present invention is not limited thereto. For example, the collector electrode 30 may alternatively include only one conductive rod 31, in which case the conductive brush 22 of the emitter electrode 20 may be oriented toward the center of the conductive rod 31, or may be oriented at a specific angle toward the conductive rod 31of the collector electrode 30.

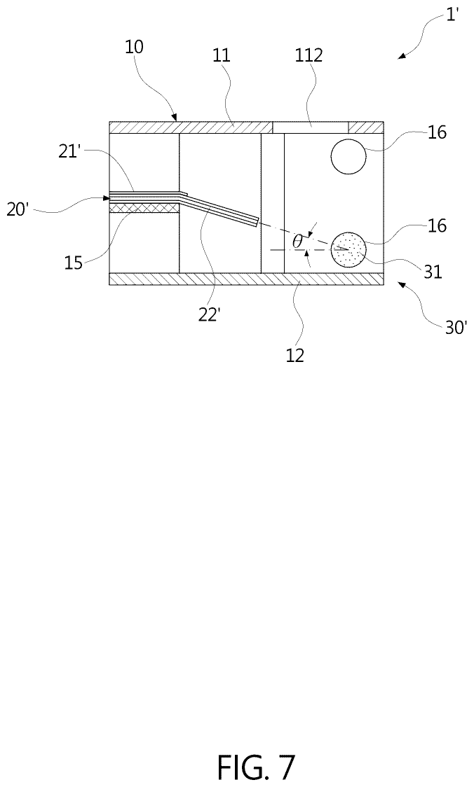

Referring to FIG. 7, FIG. 7 is a cross-sectional side view of a second embodiment of an ion wind generating/ozone removal device. Compared with the ion wind generating/ozone removal device 1 shown in FIG. 6, the collector electrode 30′ of the ion wind generating/ozone removal device 1′ shown in FIG. 7 includes only one conductive rod 31. Moreover, the connecting portion 21′ of the emitter electrode 20′ is designed to bend and extend over a small section facing the collector electrode 30′. Because the conductive fibers of the conductive brush 22′ have a diameter on the micrometer scale and are easily bent by external forces, the small bent section of the connecting portion 21′ forces the conductive fibers of the conductive brush 22′ to bend, so that the conductive brush 22′ is oriented at the specific angle θ toward the conductive rod 31 of the collector electrode 30′. The ion wind generating/ozone removal device 1′ may allow for increased airflow clearance adjacent to the air outlet 142.

The ion wind generating/ozone removal device has been described above. Referring back to FIG. 1, the heat dissipation system will now be described. Each ion wind generating device 1a is disposed on one side of the electronic component 2 with its air outlet 142 facing the electronic component 2. Each ozone removal device 1b is disposed on an opposite side of the electronic component 2 with its air inlet 141 facing the electronic component 2.

During operation, the emitter electrode 20 of the ion wind generating device 1a is electrically connected to the positive or negative terminal of a DC power source, while the collector electrode 30/30′ is electrically connected to ground or a low potential terminal close to 0 volts. The potential difference between the emitter electrode and the collector electrode of the ion wind generating device 1a is controlled, for example, between 5000 and 25000 volts. Under such a high-intensity electric field, the surrounding air is ionized or undergoes corona discharge, thereby generating a large number of ions. These ions are propelled by the electric field, driving adjacent air molecules and forming ion wind. However, the high-intensity electric field also causes oxygen molecules in the air to become ionized and recombine into ozone, which is then carried along by the ion wind.

Similarly, the emitter electrode 20 of the ozone removal device 1b is electrically connected to the positive or negative terminal of a DC power source, while the collector electrode 30/30′ is electrically connected to ground or a low potential terminal close to 0 volts. The potential difference between the emitter electrode and the collector electrode of the ozone removal device 1b is controlled, for example, between 500 and 4000 volts. Under such a low-intensity electric field, ionization or corona discharge does not occur, and thus neither ions nor ion wind are generated. However, the low-intensity electric field may stabilize charged particles and facilitate the decomposition of ozone. For example, when ozone molecules encounter negative ions, they may be reduced to ordinary oxygen, thereby achieving ozone removal.

In brief, the ion wind generating devices 1a and the ozone removal device 1b are respectively disposed on two opposite sides of the electronic component 2. The ion wind generating devices 1a operate under a high potential difference to generate ion wind and ozone, which are blown toward the electronic component 2 to assist in dissipating heat. The ozone removal device 1b operates under a low potential difference to decompose ozone. Therefore, the heat dissipation system may generate ion wind to assist in dissipating heat from the electronic component 2, while simultaneously removing the generated ozone. In one embodiment, because the ozone removal device 1b operates at a low potential difference, the conductive brush 22 of the ozone removal device 1b may be replaced with a single conductive wire. The conductive wire has two opposite ends connected to the connecting portion 21 and further has a middle portion extending substantially parallel to the conductive rod 31 of the collector electrode 30/30′. The conductive wire has a diameter of 0.05 to 5 millimeters. The conductive wire are made of conductive materials including, but not limited to, metals, alloys, conductive polymers, or carbon-based materials.

In the embodiment, three ion wind generating device 1a are arranged in a head-to-tail sequence along the y-direction. Specifically, the air outlet 142 of the first ion wind generating device 1a, which is farthest from the electronic component 2, faces the air inlet 141 of the second (middle) ion wind generating device 1a. The air outlet 142 of the second ion wind generating device 1a faces the air inlet 141 of the third ion wind generating device 1a, which is closest to the electronic component 2. The air outlet 142 of the third ion wind generating device 1a faces the electronic component 2. Accordingly, the air outlets 142 of the first and second ion wind generating devices 1a also effectively face the electronic component 2. This head-to-tail arrangement of ion wind generating devices 1a along the y-direction effectively forms a series configuration, which can provide stronger airflow. However, the present invention is not limited thereto. Provided that they can be accommodated in miniaturized electronic products, ion wind generating devices 1a may also be arranged along the x-direction and/or z-direction, as long as the air outlet 142 of each ion wind generating device 1a faces the electronic component 2. This arrangement along the x-direction and/or z-direction effectively forms a parallel configuration, which can provide greater airflow.

In the embodiment, the air inlet 141 of one of the two adjacent ion wind generating devices 1a faces the air outlet 142 of the other of the two adjacent ion wind generating devices 1a, such that a spacing between the air inlet 141 and the air outlet 142 of the two adjacent ion wind generating devices is between 3 and 20 millimeters, thereby allowing space for the emitter electrode 20 electrically connected to the positive or negative terminal of a DC power source, and the collector electrode 30/30′ electrically connected to ground or a low potential terminal close to 0 volts. Specifically, the air outlet 142 of the first ion wind generating device 1a faces the air inlet 141 of the second ion wind generating device 1a, with a spacing between 3 and 20 millimeters; the air outlet 142 of the second ion wind generating device 1a faces the air inlet 141 of the third ion wind generating device 1a, with a spacing between 3 and 20 millimeters.

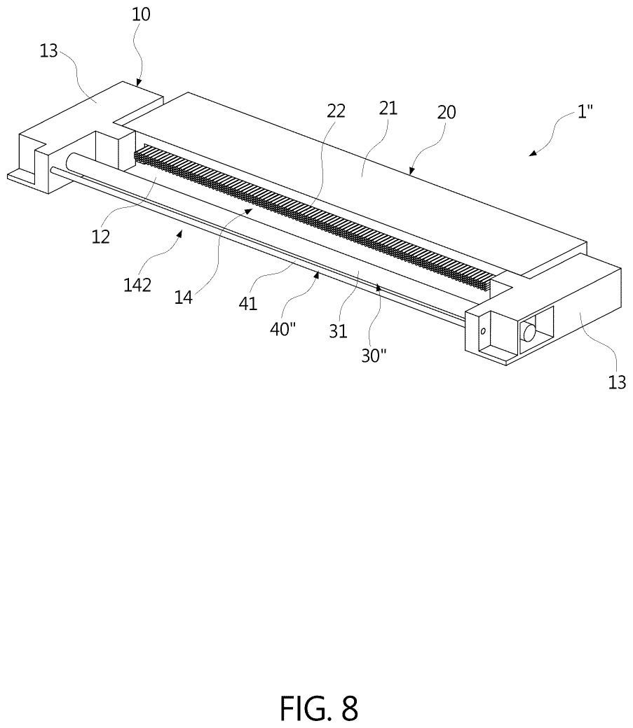

FIG. 8 is a perspective view of a third embodiment of an ion wind generating device, where the top wall 11 of the insulating frame 10 is omitted. Compared with the ion wind generating/ozone removal device 1 shown in FIG. 3, the collector electrode 30″ of the ion wind generating device 1″ shown in FIG. 8 includes only one conductive rod 31. Moreover, the ion wind generating device 1″ further includes a second emitter electrode 40″, and the collector electrode 30″ is disposed between the emitter electrode 20 and the second emitter electrode 40″. The second emitter electrode 40″ includes a second conductive rod 41. The second conductive rod 41 is disposed adjacent to the air outlet 142 and has two opposite ends respectively connected to the two side walls 13. In the embodiment, a spacing between the second emitter electrode 40″ and the collector electrode 30″ is between 0.1 and 10 millimeters, and the second conductive rod 41 has a diameter of 0.1 to 5 millimeters.

During operation, the emitter electrode 20 of the ion wind generating device 1″ is electrically connected to the positive or negative terminal of a DC power source, while the collector electrode 30″ is electrically connected to ground or a low potential terminal close to 0 volts. A potential difference, for example between 5000 and 25000 volts, is applied between the emitter electrode 20 and the collector electrode 30″ to generate ion wind and ozone, which are blown toward the electronic component 2 to assist in dissipating heat. Meanwhile, the second emitter electrode 40″ is electrically connected to the positive or negative terminal of a DC power source, while the collector electrode 30″ is electrically connected to ground or a low potential terminal close to 0 volts. A potential difference, for example between 500 and 4000 volts, is applied between the second emitter electrode 40″ and the collector electrode 30″ to decompose ozone.

Although the present invention has been described with reference to the preferred embodiments, it is not intended to be limited thereto. Various modifications and variations may be made by those skilled in the art without departing from the spirit and scope of the present invention. Therefore, the scope of protection of the present invention shall be defined by the following claims.

What is claimed is:

1. An ion wind generating device comprising:
an insulating frame comprising a top wall, a bottom wall, and two opposing side walls, the top wall, the bottom wall, and the two side walls defining an accommodation space, the accommodation space having an air inlet and an air outlet, inner surfaces of the two side walls forming inwardly inclined surfaces from the air inlet toward the air outlet, the insulating frame further comprising a bracket, the bracket being disposed adjacent to the air inlet and having two opposite ends respectively connected to the two side walls;
an emitter electrode comprising a connecting portion and a conductive brush connected to the connecting portion, the conductive brush comprising densely arranged conductive fibers, the connecting portion being mounted on the bracket; and
a collector electrode comprising at least one conductive rod, each conductive rod being disposed adjacent to the air outlet and having two opposite ends respectively connected to the two side walls.

2. The ion wind generating device of claim 1, wherein the inner surfaces of the two side walls respectively and sequentially form, from the air inlet toward the air outlet, a first guiding surface, the inclined surface, and a second guiding surface.

3. The ion wind generating device of claim 2, wherein the inner surfaces of the two side walls further respectively form a protrusion between the inclined surface and the second guiding surface, and the emitter electrode does not extend beyond the protrusion.

4. The ion wind generating device of claim 3, wherein a spacing between the emitter electrode and the collector electrode is between 1 and 10 millimeters, the protrusion has a length of 1 and 10 millimeters, the connecting portion has a length of 2 to 10 millimeters and a width of 2 to 10 millimeters, the conductive fibers of the conductive brush have a length of 2 to 10 millimeters, and the conductive rod has a diameter of 0.5 to 5 millimeters.

5. The ion wind generating device of claim 1, wherein the two side walls are respectively provided with at least two connecting holes adjacent to the air outlet, and each conductive rod has two opposite ends respectively connected to the at least two connecting holes of the two side walls.

6. The ion wind generating device of claim 1, wherein the bracket comprises a horizontal supporting plate and a vertical supporting plate, the horizontal supporting plate having two opposite ends respectively connected to intermediate-height portions of the two side walls, the vertical supporting plate having two opposite ends respectively connected to a middle portion of the horizontal supporting plate and the bottom wall.

7. The ion wind generating device of claim 1, wherein the conductive brush is oriented at a specific angle toward the conductive rod of the collector electrode.

8. The ion wind generating device of claim 1, wherein the conductive fibers of the conductive brush comprise carbon fibers, conductive polymer fibers, carbon black-based fibers, or conductive metal compound fibers, the conductive rod is made of titanium alloy, nickel-plated plastic, nickel-plated copper, nickel-plated copper alloy, nickel-plated aluminum, nickel-plated aluminum alloy, nickel-plated zinc, nickel-plated zinc alloy, stainless steel, or Nak80 steel.

9. The ion wind generating device of claim 1, further comprising a second emitter electrode, the collector electrode being disposed between the emitter electrode and the second emitter electrode, the second emitter electrode comprising a second conductive rod, the second conductive rod being disposed adjacent to the air outlet and having two opposite ends respectively connected to the two side walls.

10. The ion wind generating device of claim 9, wherein a spacing between the second emitter electrode and the collector electrode is between 0.1 and 10 millimeters, and the second conductive rod has a diameter of 0.1 to 5 millimeters.

11. A heat dissipation system for an electronic component, comprising at least one ion wind generating device and at least one ozone removal device, wherein each of the at least one ion wind generating device and the at least one ozone removal device comprises:
an insulating frame comprising a top wall, a bottom wall, and two opposing side walls, the top wall, the bottom wall, and the two side walls defining an accommodation space, the accommodation space having an air inlet and an air outlet, inner surfaces of the two side walls forming inwardly inclined surfaces from the air inlet toward the air outlet, the insulating frame further comprising a bracket, the bracket being disposed adjacent to the air inlet and having two opposite ends respectively connected to the two side walls;
an emitter electrode comprising a connecting portion and a conductive brush connected to the connecting portion, the conductive brush comprising densely arranged conductive fibers, the connecting portion being mounted on the bracket; and
a collector electrode comprising at least one conductive rod, each conductive rod being disposed adjacent to the air outlet and having two opposite ends respectively connected to the two side walls;
wherein each ion wind generating device is disposed on one side of the electronic component with its air outlet facing the electronic component, and each ozone removal device is disposed on an opposite side of the electronic component with its air inlet facing the electronic component; wherein a potential difference between the emitter electrode and the collector electrode of each ion wind generating device is configured to generate ion wind and ozone, and a potential difference between the emitter electrode and the collector electrode of each ozone removal device is configured to decompose the ozone.

12. The heat dissipation system of claim 11, wherein the potential difference between the emitter electrode and the collector electrode of each ion wind generating device is between 5000 and 25000 volts, and the potential difference between the emitter electrode and the collector electrode of each ozone removal device is between 500 and 4000 volts.

13. The heat dissipation system of claim 11, wherein the number of the ion wind generating devices is two or more, and the air inlet of one of the two adjacent ion wind generating devices faces the air outlet of the other of the two adjacent ion wind generating devices, wherein a spacing between the air inlet and the air outlet of the two adjacent ion wind generating devices is between 3 and 20 millimeters.

14. The heat dissipation system of claim 11, wherein the conductive brush of each ozone removal device is replaced by a conductive wire, the conductive wire having two opposite ends connected to the connecting portion and a middle portion extending parallel to each conductive rod of the collector electrode.

15. The heat dissipation system of claim 14, wherein the conductive wire has a diameter of 0.05 to 5 millimeters.

16. The heat dissipation system of claim 11, wherein the inner surfaces of the two side walls respectively and sequentially form, from the air inlet toward the air outlet, a first guiding surface, the inclined surface, and a second guiding surface.

17. The heat dissipation system of claim 16, wherein the inner surfaces of the two side walls further respectively form a protrusion between the inclined surface and the second guiding surface, and the emitter electrode does not extend beyond the protrusion.

18. The heat dissipation system of claim 17, wherein a spacing between the emitter electrode and the collector electrode is between 1 and 10 millimeters, the protrusion has a length of 1 and 10 millimeters, the connecting portion has a length of 2 to 10 millimeters and a width of 2 to 10 millimeters, the conductive fibers of the conductive brush have a length of 2 to 10 millimeters, and the conductive rod has a diameter of 0.5 to 5 millimeters.

19. The heat dissipation system of claim 11, wherein the conductive brush is oriented at a specific angle toward the conductive rod of the collector electrode.

20. The heat dissipation system of claim 11, wherein the conductive fibers of the conductive brush comprise carbon fibers, conductive polymer fibers, carbon black-based fibers, or conductive metal compound fibers, the conductive rod is made of titanium alloy, nickel-plated plastic, nickel-plated copper, nickel-plated copper alloy, nickel-plated aluminum, nickel-plated aluminum alloy, nickel-plated zinc, nickel-plated zinc alloy, stainless steel, or Nak80 steel.
